(19) United States
(12) Patent Application Publication
(10) Pub. No.: US 2010/0127904 A1
(43) Pub. Date: May 27, 2010

(54) IMPLEMENTATION OF A RAPID ARITHMETIC BINARY DECODING SYSTEM OF A SUFFIX LENGTH

(75) Inventors: Gedalia Oxman, Tel Aviv (IL); Michael Khrapkovsky, Herzliya (IL)

Correspondence Address: KEVIN D. MCCARTHY;ROACH BROWN MCCARTHY & GRUBER, P.C., 424 MAIN STREET, 1920 LIBERTY BUILDING, BUFFALO, NY, 14202, US

(73) Assignee: HORIZON SEMICONDUCTORS LTD., Herzliya (IL)

(21) Appl. No.: 12/323,676

(22) Filed: Nov. 26, 2008

(51) Int. Cl. H03M 7/00

(52) U.S. Cl. 341/107

(57) ABSTRACT

The present invention relates to a system for the parallel processing of a number of binstream bins comprising: (a) inputs for receiving the codIOffset, the codIRange and the bitstream suffix bits; (b) a first circuit for the parallel processing of said number of said bitstream suffix bits, said codIOffset, and said codIRange for producing an indication of the binstream suffix length magnitude; (c) a second circuit for the parallel processing of said number of said bitstream suffix bits, said codIOffset, and said codIRange for producing said number of speculative codIOffsets; (d) a third circuit for combining the products of said first circuit and the products of said second circuit for producing a new codIOffset; and (e) a fourth circuit for combining the products of said first circuit with said number of constants for producing a number indicative of the binstream suffix length.

### FIELD OF THE INVENTION

The present invention relates to the field of digital video decoding systems. More particularly, the invention relates to a system for the simultaneous parallel decoding of a number of suffix bits from an encoded bitstream, according to the context adaptive binary arithmetic decoding scheme described in the H.264 standard.

### BACKGROUND OF THE INVENTION

The increasing demand to improve the quality of transmitted video has prompted rapid advancements in video compression techniques. During the last decade, many ISO/ITU standards on video compression have evolved, such as standard ISO/14496-10:2005 AVC referred to hereinafter as the H.264 standard. This standard exploits the spatial and temporal correlation in the video data and utilizes entropy coding techniques to achieve a high compression ratio. One of the standard's compression techniques uses the DCT transform, which can transform a block of an image pixel into coefficients that are energy concentrated around the low frequency region, effectively exploiting the spatial correlation of the video. Another technique disclosed in the H.264 standard is the use of motion vectors which are two-dimensional vectors used for inter prediction that provide an offset from the coordinates in the decoded picture to the coordinates in a reference picture, effectively exploiting the temporal correlation of the video. Entropy coding is a loss-less compression process that is based on the statistical properties of data. The entropy machines first assign codes to symbols so as to match code lengths with the probabilities of occurrence of the symbols. The basic idea is to express the most frequently occurring symbols with the least number of bits.

Due to its high compression efficiency, the Arithmetic coding has been chosen for the H.264 standard as the higher compression mode. The H.264 supported arithmetic coding is combined with context-adaptive modeling techniques and is known as the Context-based Adaptive Binary Arithmetic Coding (CABAC). The context-adaptive modeling techniques use local spatial and temporal characteristics to estimate the probability of a symbol. Thus, context-adaptive modeling has shown an even better compression results compared to the other forms of coding, as the successful entropy coding depends largely on accurate models of symbol probability.

The CABAC encoding algorithm includes three basic steps: binarization, context modeling, and binary arithmetic encoding. In the H.264 standard, context modeling and the binary arithmetic engine approximate the generic arithmetic encoder using quantization.

At first, a syntax element, is mapped to a unique binary sequence of bins called binstring. The process of converting a syntax element value to a binary sequence is referred to hereinafter as binarization,

Arithmetic coding is based on the principle of recursive interval subdivision. Given a probability estimation p(‘0’) and p(‘1’)=1−p(‘0’) of a binary decision (‘0’, ‘1’), an initially given interval with lower bound L and with range R will be subdivided into two sub-intervals having range p(‘0’)×R and R−p(‘0’)×R, respectively. Depending on the decision, which has been observed, the corresponding sub-interval will be chosen as the new code interval, and a binary code string pointing into that interval will represent the sequence of observed binary decisions. It is useful to distinguish between the most probable symbol (MPS) and the least probable symbol (LPS), so that binary decisions have to be identified as either MPS or LPS, rather than ‘0’ or ‘1’. Given this terminology, each context model CTX is defined by the probability pLPS of the LPS and the value of MPS, which is either ‘0’ or ‘1’.

The range R representing the state of the coding engine is quantized to a small set {Q1, . . . ,Q4} of pre-defined quantization values prior to the calculation of the new interval range. Versus generic arithmetic encoding, storing a table containing all 64×4 pre-computed product values of Qi×Pk allows a multiplication-free approximation of the product R×Pk.

For syntax elements or parts thereof with an approximately uniform probability distribution a separate simplified bypass encoding and decoding path is used.

In the context modeling step, each bin is assigned a probability context model, which includes information on whether the bin is most likely to be ‘1’ or ‘0’, as well as the numeric probability of the bin to be the least likely bin (which implies the numeric probability of the most likely bin as well) In the H.264 standard the probability estimation is performed by means of a finite-state machine with a table-based transition process between 64 different representative probability states {Pk|0≦k<64} for the LPS probability pLPS.

In the H.264 standard, the binarization mappings are either specifically defined or are obtained by a combination of four elementary binarization processes. The four elementary binarization processes are Unary binarization process, the Truncated Unary (TU) binarization process, the Concatenated Unary/K-th order Exp-Golomb (EGk) binarization process, and the Fixed-Length binarization process. For example, the DCT transform coefficient types have a binarization which is a combination of TU binarization and EGk binarization. In other words, a DCT transform coefficient is first partitioned into 2 syntax elements, each syntax element is binarized differently and then the binarizations are concatenated together. The first syntax element is binarized using the TU binarization process and is called a prefix, whereas the second syntax element is binarized using the EGk binarization process, and is called the suffix.

Despite its higher coding efficiency, one main disadvantage of Arithmetic coding lies in its inherent sequential nature. The inherent sequential nature poses an even greater burden during decoding, where processing time is crucial and delays during decoding and displaying are unacceptable. The inherent sequential nature and the computational complexity hamper the adoption of CABAC in speed requiring devices and other processing devices. Keeping in view the fact that H.264 is expected to supersede all previous video coding standards, it may be appreciated that it would be desirable to develop systems that are capable of decoding the bitstream faster.

U.S. Pat. No. 7,262,722 discloses a CABAC decoder with parallel binary arithmetic decoding which includes a first, second and third pairs of look-up tables and first, second and third multiplexers. The tables and multiplexers are used and controlled in common in order to decode a number of bits simultaneously. Nevertheless, the described system is fairly slow and depends on the number of lookup tables, meaning that in order to process more bits in parallel, more lookup tables and multiplexers are needed, which in return slow the process and increase the overall complexity and cost of the system.

As stated above, one of the binarization processes is the TU binarization process. In order to execute the TU binarization process a cMax parameter, also known as the “cutoff” parameter, is required. The TU binarization process maps each syntax element's value, smaller than cMax, to a binary sequence consisting a number, equal to the element's value, of ‘1’s and a ‘0’ at the sequence's end. If the element's value is equal to cMax it is converted to a sequence having a number (equal to the element's value, i.e. the eMax value) of ‘1’s, without a ‘0’ at the end. Thus, for example, if cMax=4 and the syntax element's value is 3 then its corresponding TU binary sequence is ‘1110’ However, if cMax=4 and the syntax element's value is 4 then its corresponding TU binary sequence is ‘1111’.

Another binarization process is the EGk binarization process. The EGk binarization process, as described in the H.264 standard, is more complex and can be shown as an output of the C++ microcode shown in FIG. 1a. In the displayed microcode, ‘x’ is the value of the syntax element and ‘k’ is the order of the EGk. For example if x=“3” and k=0, then the EG0 binary sequence is ‘11000’. Different types of syntax elements may belong to different ‘k’ orders.

FIG. 1b depicts a table illustrating an example of the binarization of a DCT transform coefficient according to the H.264 standard. Before the transformation coefficients are binarized, each coefficient value is subtracted by “1”, for efficiency reasons, as the coefficient value of “0” is handled differently in the standard. The new “coefficient value−1” is referred to hereinafter as “Y”. In this example, for the TU prefix, the cMax=“14”. When the Y is less than 14, it is mapped to a TU binary sequence consisting of a continuation of ‘1’ bits and terminating with a ‘0’ bit. On the other hand, when the value of Y is larger or equal to 14, the prefix part, valued 14, is mapped to a TU code, and the remaining suffix part, which is the Y value subtracted by the prefix value (i.e. “14”), is mapped to an EGk binary sequence having an order of “0” (k=0). An EGk binarization code having an order of 0 is referred to hereinafter as “EG0”. Thus, different binarization processes are used depending on the magnitude of the coefficient's value, in order to adaptively apply higher probabilities to smaller values that occur more frequently in the binarization and significantly increase arithmetic coding efficiency. Thus, each coefficient value larger than “14” is mapped to a binary sequence which is a concatenated scheme derived from the TU and the EG0 binarization processes.

As stated in the H.264 standard, the compressed video elements are binarized, CAVLC or CABAC encoded, and packaged into the bitstream according to a pre-determined syntax order as defined in section 7.3 of the standard. The suffix binary sequence of the binarization of the DCT transform coefficient is processed and encoded into a bitstream as part of the residual syntax in section 7.3.5.3, Thus when the decoding machine receives a bitstream for decoding and displaying it can easily find the bits belonging to the suffix within the encoded bitstream by decoding the bitstream serially according to section 7.3 of the H.264 standard.

FIG. 2 depicts a table showing an example of the suffix of the binarization of a DCT transform coefficient, as described in relations to FIG. 1b, according to the H.264 standard. As shown the suffix has two parts, the first part which is referred to hereinafter as the “length” and second part which is referred to hereinafter as the “tail”. The length part, which is always terminated by ‘0’ indicates the length of the tail, where the number of ‘1’s in the sequence indicates the number of bits in the tail. For example, if the length sequence is ‘110’ the tail has “2” bins. As stated above in relations to FIG. 1b, the x, in this case, is equal to Y−14. The binarized suffix length may be used in binarized form as shown in the table of FIG. 2, or in decimal form, according to the needs and requirements.

More information may be found in the publication: “Context Based Adaptive Binary Arithmetic Coding in H.264/AVC Video Compression Standard” by Detlev Marpe, Heiko Schwarz and Thomas Wiegand, IEEE transactions on circuits and systems for video technology, Vol. 13, No. 7, July 2003.

FIG. 3 depicts a generic decoding system used for decoding and displaying transmitted digital video contents. The bitstream source 100 may receive the video bitsreams over cable, through the internet, over the air, through terrestrial communication, or any other communication medium used for transmitting digital video signals. Once the bitstream source 100 receives the encoded video bitstreams its task is to timely feed these bitstreams into decoding system 220 for processing. At first, the decoding system 220 receives the encoded bitstreams and starts decoding them. During decoding some of the bitstreams are also decoded to their binarized sequences. The binarized sequences are then converted into their original syntax elements using the reverse binarization process. The syntax elements are then further processed into a video stream ready for display. The video stream is then sent from the decoding system 220 to display unit 300 for display. Inside the decoding system 220 lies the decoder circuit (not shown) which decodes the designated bitstreams into binarized sequences. The decoder circuit comprises a number of sub-decoders for processing different types of bitstreams. One of these sub-decoders is responsible for processing the bitstream belonging to the suffix. The essence of the invention lies in the implementation of the sub-decoder capable of parallel processing a number of bits in the bitstream belonging to the suffix length.

The status of the arithmetic decoding engine is represented by a value codIOffset pointing into the code sub-interval and the corresponding range codIRange of that sub-interval. At the beginning of the decoding process, codIRange is set to 510, codIOffset is set by reading 9 bits from the bitstream, as described in section 9.3.1.2 of the standard. Then for decoding of each single binary decision, the following two-step operation is employed: first, the related context model is determined according to the rules specified in section 9.3.3.1 of the standard, and then the binary decision is decoded as specified in section 9.3.3.2. As described in the H.264 standard, the bin can then be decoded using the regular or the bypass decoding process.

As stated above in relations to FIG. 2, the suffix length indicates the number of bins in the tail, a trait which allows the calculation of the maximum possible length. In addition, as specified in section 9.3.2, table 9-25, the suffix length is decoded using the CABAC bypass decoding process as described in the H.264 standard. The CABAC encoder is using the bypass encoder process in conjunction with syntax elements that are uniformly distributed, for which the probability of the encoded bin being 0 or 1 is the same probability, and therefore the current interval is always divided in the encoder into two equal parts, and therefore each single bin is encoded by a single bit. The bypass decoding process is described in the H.264 standard section 9.3.2.3. For these binarization processes, the prefix and the suffix bit strings are separately indexed as specified in sub clause 9.3.3 of the H.264 standard.

FIG. 4 is a flowchart illustrating the bypass decoding process for a single bit from the bitstream, as disclosed in section 9.3.3.2.3 of the H.264 standard. In step 1 three parameters are received: codIOffset, codIRange and a bit, all of which are deduced from the received bitstream. In step 2 the codIOffset bits are moved one space left (i.e. codIOffset is multiplied by two), and the bit of the bitstream is placed in the LSB of codIOffset. In step 3 the codIOffset value is compared to the codIRange value. If the codIOffset is smaller than the codIRange then the bin outcome is equal to ‘0’, however, if the codIOffset is larger or equal to the codIRange, then the bin outcome is equal to ‘1’ and codIRange is deduced from the codIOffset to generate the new codIOffset. In both cases the process for a single bin is finished in step 6. The next bit may be processed accordingly with the new codIOffset.

FIG. 5 is a flowchart illustrating the decoding process for the suffix length as derived from FIG. 4 and according to the H.264 standard. In step 11 three parameters of the suffix are received: codIOffset, codIRange and the bitstream of the suffix. In step 12 the codIOffset bits are moved one space left (i.e. codIOffset is multiplied by two), and the first bit of the suffix bitstream is placed in the LSB of codIOffset. In stop 13 the codeIOffset value is compared to the codIRange value. If the codIOffset is larger or equal to the codIRange, then the first bin is equal to ‘1’, the new codIRange is deduced from the codIOffset, and steps 12-14 are repeated until the codIOffset is smaller than the codIRange. When the codIOffset is smaller than the codIRange then a bin equal to ‘0’ is added to the binstring effectively ending the process of decoding the suffix length binstring in step 16. Nevertheless, as shown, the described decoding process has a sequential nature requiring revaluation of the codIOffset before each new bit can be processed, a trait which can cost precious processing time and burden the implementation of this process with many processing cycles which multiply as the number of bits required for process increase.

FIG. 6 is a schematic diagram of a prior art implementation of the process described in relations to FIG. 5. Block 101 receives as input the codIOffset, codIRange and the first bit of the suffix bitstream. As described in relation to FIG. 5, the codIOffset bits are first moved one space left and the received first bit is added to codIOffset, in concatenator 201. In other words, Bit1 is concatenated to the codIOffset. The codIRange value is then subtracted from the concatenated codeIOffset value in subtractor 202. If the result is positive, then the MUX 204 will output a “1”, and the MUX 203 will output the subtractor's 202 result as the new codIOffset. If the result is negative, then the MUX 204 will output a “0”, and the MUX 203 will output the concatenator 201 output. Blocks 102, 103 and 104 perform similarly to block 101. Thus a number of blocks may be connected in order to process a number of bits. However, since each block waits for the codIOffset input from the last block, the total processing time equals to the total processing time of all the blocks added together. This sequential process requires a long processing time, especially when dealing with a big number of bits. For the sake of brevity the above description dealt with the processing of only 4 bits, however, in real decoding systems the suffix length decoder is sometimes required to process 16 bits.

It is an object of the present invention to provide a system for decoding a number of bits in parallel using a minimal number of processing cycles.

It is another object of the present invention to provide a hardware implementation for rapidly decoding a suffix length bitstream, according to the H.264 standard.

It is still another object of the present invention to provide a system for parallel processing of all the suffix length bits.

It is still another object of the present invention to provide a system capable of parallel processing of the suffix length bitstream for supplying the suffix length in a standard binary form.

It is still another object of the present invention to provide a system capable of parallel processing of the suffix length bitstream for supplying a new codIOffset as required by the H.264 standard.

Other objects and advantages of the invention will become apparent as the description proceeds.

### SUMMARY OF THE INVENTION

The present invention relates to a system for the parallel processing of a number of binstream bins comprising: (a) inputs for receiving the codIOffset, the codIRange and the bitstream suffix bits; (b) a first circuit for the parallel processing of said number of said bitstream suffix bits, said codIOffset, and said codIRange for producing an indication of the binstream suffix length magnitude; (c) a second circuit for the parallel processing of said number of said bitstream suffix bits, said codIOffset, and said codIRange for producing said number of speculative codIOffsets; (d) a third circuit for combining the products of said first circuit and the products of said second circuit for producing a new codIOffset; and (e) a fourth circuit for combining the products of said first circuit with said number of constants for producing a number indicative of the binstream suffix length.

Preferably, the number of bitstream suffix bits is 16.

In one embodiment, the binstream suffix length belongs to a syntax element of a DCT coefficient type.

In another embodiment, the binstream suffix length belongs to a syntax element of a Motion Vector.

Preferably, the system is also used for finding errors in the bitstream suffix bits.

Preferably, the bitstream suffix bits are fed in a terraced form into the inputs.

Preferably, the first circuit comprises: (a) inputs for receiving the codIOffset, the codIRange and said bitstream suffix bits; (b) at least one concatenator for concatenating at least one bit of said bitstream suffix to said codIOffset; (c) at least one multiplier for multiplying said codIRange by a preset constant; (d) at least one comparator for comparing products of said concatenator and said multiplier; and (e) at least one output for outputting at least one result of said at least one comparator.

Preferably, the first circuit further comprises: (f) at least one inverter for inverting at least one output of said first circuit; and (g) at least one AND gate for logically ANDing at least two outputs of said first circuit.

Preferably, the system is also used for finding errors, in the bitstream suffix bits, by finding that the outputs of the AND gates have more than one logical ‘1’.

Preferably, the preset constant is equal to the result of the function (2ⁱ⁺¹−1) where i is a whole number which starts from 0 for the first input and increases by 1 for each new input.

Preferably, the bitstream suffix bits are fed in a terraced form into the inputs of the first circuit.

Preferably, the second circuit comprises: (a) inputs for receiving the codIOffset, the codIRange and said bitstream suffix bits; (b) at least one concatenator for concatenating at least one bit of said bitstream suffix to said codIOffset; (c) at least one multiplier for multiplying said codIRange by a preset constant; (d) at least one subtracter for subtracting the product of said multiplier from said concatenator; and (e) at least one output for outputting at least one result of said at least one subtractor.

Preferably, the bitstream suffix bits are fed in a terraced form into the inputs of the second circuit.

Preferably, the preset constant is equal to the result of the function (2ⁱ⁺¹−2) where i is a whole number which starts from 0 for the first input and increases by 1 for each new input.

The present invention further relates to system for the parallel processing of a binstream suffix length in parts comprising: (a) inputs for receiving the codIOffset, the codIRange and the bitstream suffix bits; (b) a first circuit for the parallel processing of said number of said bitstream suffix bits, said codIOffset, and said codIRange for producing an indication of the binstream suffix length magnitude; (c) a second circuit for the parallel processing of said number of said bitstream suffix bits, said codIOffset, and said codIRange for producing said number of speculative codIOffsets; (d) a third circuit for combining the products of said first circuit and the products of said second circuit for producing a new codIOffset; (e) a fourth circuit for combining the products of said first circuit with said number of constants for producing a binstream suffix length; (f) a fifth circuit for subtracting said codIRange from the last output of the second circuit for producing a codIOffset ready for input for said first circuit and said second circuit of the next part; and (g) a sixth circuit for detecting if one of the outputs of said first circuit is a logical ‘1’.

Preferably, the bitstream suffix bits are fed in a terraced form into the inputs.

Preferably, the fifth circuit comprises: (a) an input for receiving the codIRange; (b) an input for receiving the last codIOffset output from the second circuit; (c) a subtractor for subtracting said codIRange from codIOffset; and (d) an output for outputting the result from said subtractor as a codIOffset for the next part of said parallel processing of said system. Preferably, the system is also used for finding errors in the bitstream suffix bits.

Preferably, the sixth circuit is used for error detecting.

### BRIEF DESCRIPTION OF THE DRAWINGS

In the drawings:

FIG. 1a is an example of a microcode for computing the suffix according to the H.264 standard,

FIG. 1b depicts a table illustrating an example of the binarization of a DCT transform coefficient according to the H.264 standard.

FIG. 2 depicts a table showing an example of the suffix of the binarization of a DCT transform coefficient according to the H.264 standard.

FIG. 3 depicts a generic decoding system used for decoding and displaying transmitted digital video contents.

FIG. 4 is a flowchart illustrating the bypass decoding process for a single bin from the bitstream according to the H.264 standard.

FIG. 5 is a flowchart illustrating the decoding process for the suffix length.

FIG. 6 is a schematic diagram of a prior art implementation of the processing of four suffix length bits.

FIG. 7 is a block diagram of a hardware implementation of the simultaneous parallel processing of 4 bitstream suffix length bits, according to one embodiment.

FIG. 8 is a block diagram of an implementation of a codIOffset speculation circuit, according to an embodiment of the invention.

FIG. 9 is a block diagram illustrating the combination of the 4-bin processing circuit with the 4-bin speculation circuit, according to an embodiment of the invention.

FIG. 10 is a block diagram illustrating an implementation of a function for combining bits, according to an embodiment of the invention.

### DETAILED DESCRIPTION OF PREFERRED EMBODIMENTS

The following terms are described explicitly:

Bitstream—a sequence of bits that forms the representation of coded pictures and associated data forming one or more coded video sequences, which is encoded by the encoding system, according to the H.264 standard. The bitstream may be received over cable, through the internet, over the air, through terrestrial communication, or any other communication medium used for transmitting digital signals.

Syntax Element—an element of data represented in the bitstream. Different Syntax Elements can represent different types of data (e.g. motion vectors, DCT coefficients, etc.)

Bin—a binary digit, which is the binary decision of the arithmetic decoder.

Bin string—a string of bins, which is an intermediate binary representation of a value of a syntax element.

Binstream—a sequence of bin strings. The bitstream is converted to a binstream using the H.264 CABAC decoding process as defined in the standard.

Binarization—a bin string representing a value of a syntax element.

Binarization process—a unique mapping process of a syntax element's value onto a bin string.

codIOffset,—a 9 bits state variable of the arithmetic decoding engine, pointing into the code sub-interval.

codIRange—a 9 bit state variables of the arithmetic decoding engine, representing the range of the code sub-interval.

encoded bitstream—a bitstream, binarized (using the binarization process) and encoded by the encoding system, according to the H.264 standard,

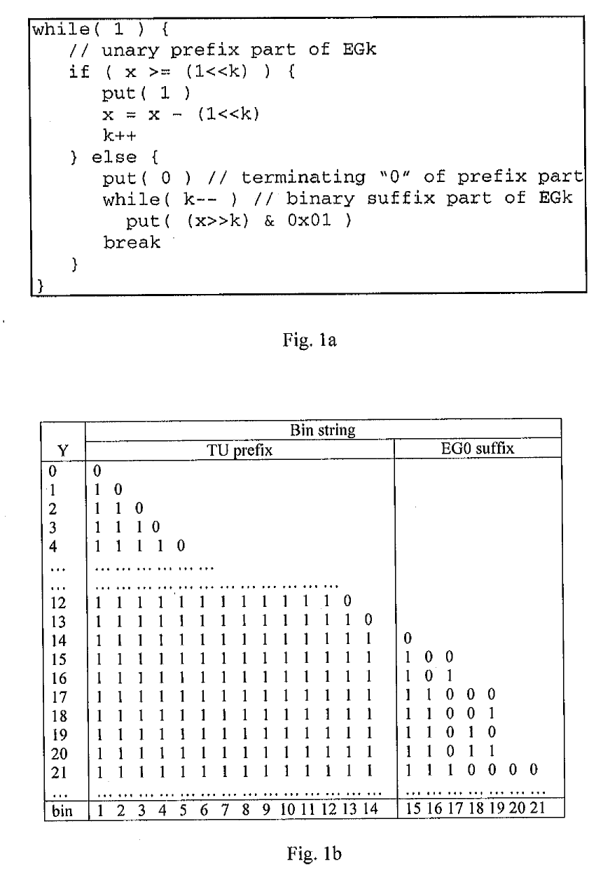

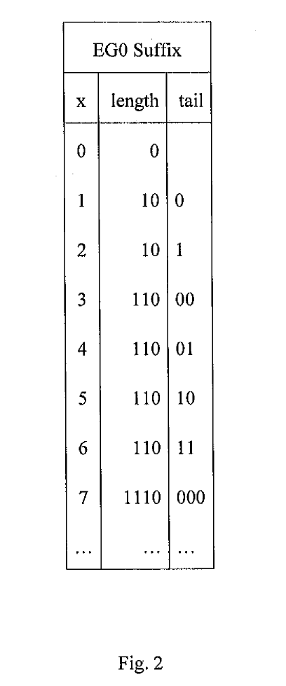

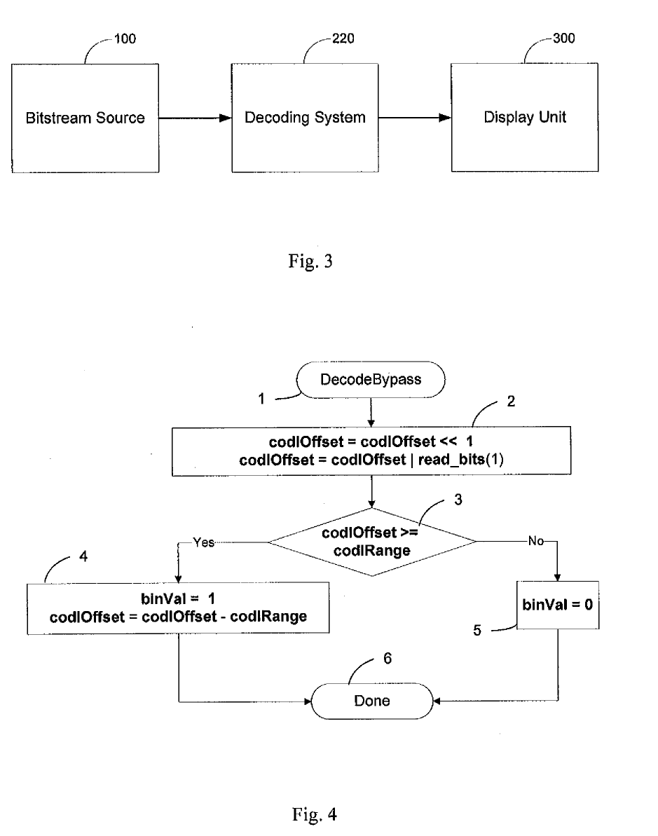

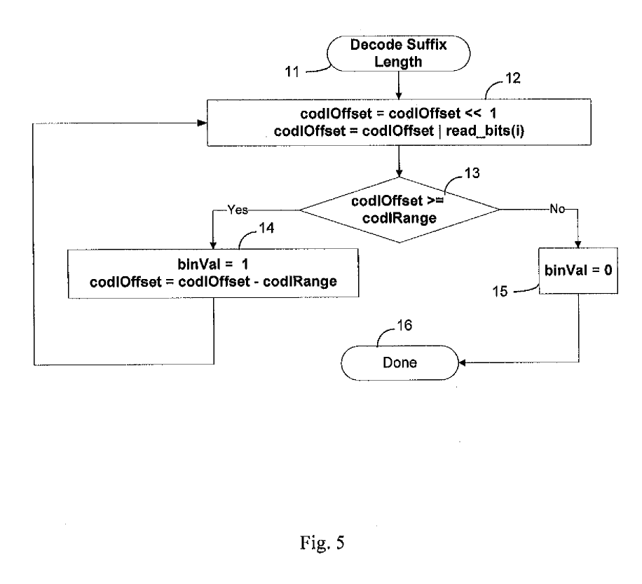

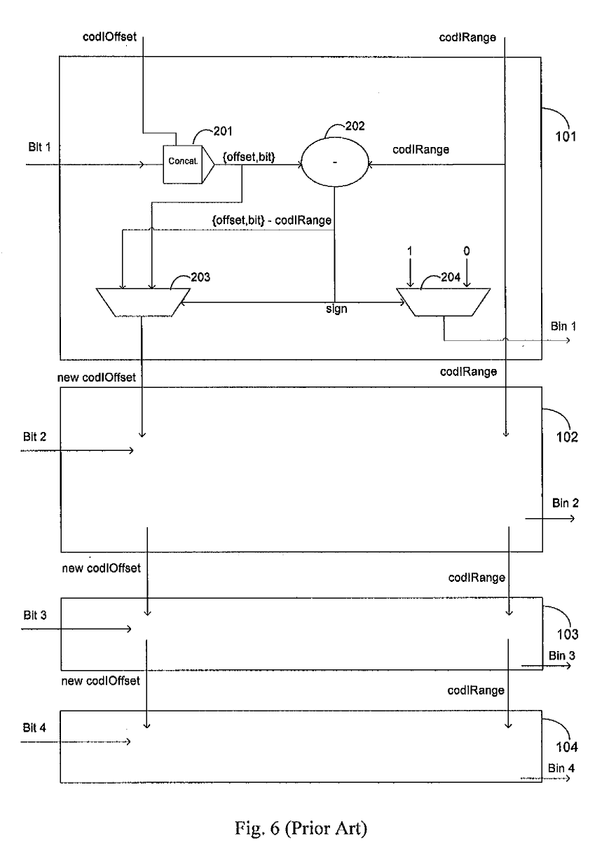

Binarized suffix length—as described in relations to FIG. 1a, FIG. 1b and FIG. 2.

Binstream suffix—the next bins, of the encoded binstream, located after the bins processed as the prefix of the syntax element.

Bitstream suffix—the next bits, of the encoded bitstream, located after the bits processed as the prefix of the syntax element, and used for decoding the binstream suffix. In the bypass decoding process, a single bit from the bitstream is processed each time for decoding a single bin.

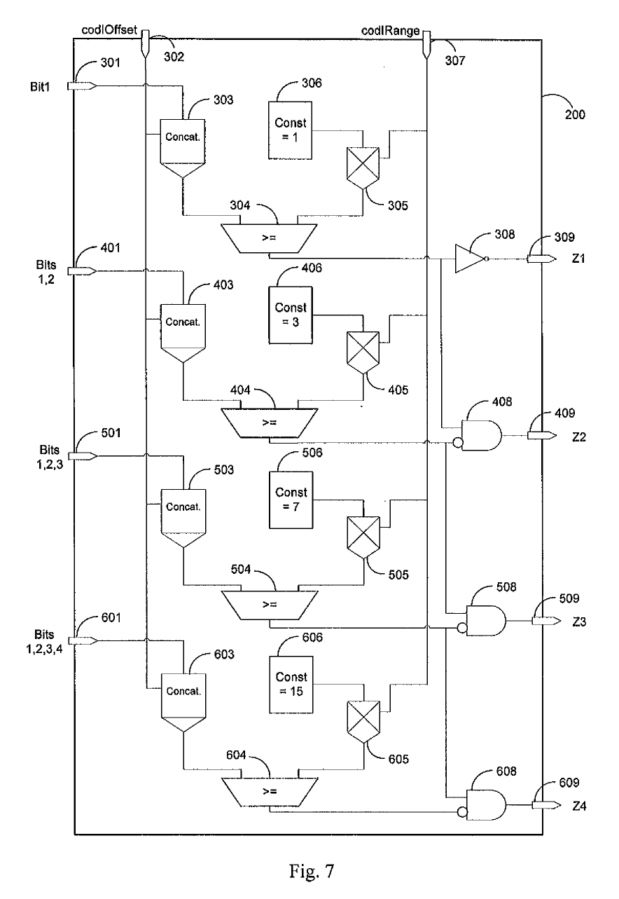

FIG. 7 is a block diagram of a hardware implementation of the simultaneous parallel processing of 4 binstream suffix length bins, according to one embodiment. For the sake of brevity the following description deals with an implementation capable of processing 4 bins, although the invention may be implemented for other desirable numbers of bins. The input parameters of the circuit 200 are the CABAC arithmetic decoder state variables codIOffset, codIRange and the first 4 bits of the suffix part of the received bitstream, labeled Bit1, Bit2, Bit3, and Bit4, where Bit1 is the next bit in the ordered encoded bitstream after the prefix. All these parameters are retrieved from the encoded bitstream. At first, Bit1 from input 301 is concatenated to the right end (i.e. to the LSB) of codIOffset sequence from input 302 using concatenator 303. The concatenation process is very fast in terms of processing time, and mathematically it is equivalent to multiplying the codIOffset by “2” and adding Bit1. At the same time, CodIRange from input 307 is multiplied, using multiplier 305, by a constant of 1, stored in buffer 306. The concatenated result from concatenator 303 and the multiplied result from multiplier 305 are compared by comparator 304. If the result from concatenator 303 is larger or equal to the multiplied result from multiplier 305 then comparator 304 produces a ‘1’, otherwise, comparator 304 produces a ‘0’. The produced result of comparator 304 is then inverted by inverter 308 and sent to output 309. The bit from output 309 is referred to hereinafter as Z1. Simultaneously to the above described process, Bit1 and Bit2 from input 401 are processed similarly by the components 403-406 which function as components 303-306 respectively, excluding the constant in buffer 406 which is a “3”. The concatenation process of concatenator 403 is mathematically equivalent to multiplying the codIOffset by “2”, adding Bit1, multiplying the result by “2” and adding Bit2. The produced result of comparator 404 is then inverted, and a logical AND operation is done with the result of comparator 304, by the “AND” logic gate 408, and the outcome is sent to output 409. The bit from output 409 is referred to hereinafter as Z2. The other two inputs: from input 501 (3 bits: Bit1, Bit2, and Bit3) and from input 601 (4 bits: Bit1, Bit2, Bit3, and Bit4), are also processed similarly by components 503-506 and 603-606 respectively. Components 503-506 function similarly to components 403-406 respectively, excluding the constant in buffer 506 which is a 7, and components 508-509 function similarly to components 408-409, where the bit from output 509 is referred to hereinafter as Z3. Components 603-606 function similarly to components 403-406 respectively, excluding the constant in buffer 606 which is a 15, and components 608-609 function similarly to components 408-409, where the bit from output 609 is referred to hereinafter as Z4. Thus the system processes the 4 terraced inputs separately and simultaneously, for producing a total outcome of 4 bits labeled Z1-Z4. By terraced inputs it is meant to include the first input that is a single bit and the other inputs which are each a concatenation of single bit of a prior input. The constants required for storage in buffers 306, 406, 506, and 606 can be derived using this function:

Const=2ⁱ⁺¹−1

where i is a whole number which starts from 0 for the first input and increases by 1 for each new input. Since all the constants are known before implementation, they may be hardwired in the system 200 during fabrication.

For the sake of brevity an example is set forth for demonstrating the process of circuit 200 as described in relations to FIG. 7. In this example, codIOffset=“400” and codIRange=“500” and the first 4 bits of the suffix part of the received bitstream are: Bit1=‘1’, Bit2=‘1’, Bit3=‘0’, and Bit4=‘0’. Concatenator 303 concatenates Bit1 to the codIOffset which produces “801”. Multiplier 305 produces the codIRange multiplied by “1” which is “500”. Comparator 304 produces a ‘1’ which is inverted by inverter 308, effectively achieving Z1=‘0’. Concatenator 403 concatenates Bit1 and Bit2 to the codIOffset which produces “1603”. Multiplier 405 produces the codIRange multiplied by “3” which is “1500”. Comparator 404 produces a ‘1’ which is inverted and logically ANDed with the result from comparator 304, effectively achieving Z2=‘0’. Concatenator 503 concatenates Bit1, Bit2 and Bit3 to the codIOffset which produces “3206”. Multiplier 505 produces the codIRange multiplied by “7” which is “3500”. Comparator 504 produces a “0” which is inverted and logically ANDed with the result from comperator 404, effectively achieving Z3=‘1’. Concatenator 603 concatenates Bit1, Bit2, Bit3 and Bit4 to the codIOffset which produces “6412”. Multiplier 605 produces the codIRange multiplied by “15” which is “7500”. Comparator 604 produces a ‘0’ which is inverted and logically ANDed with the result from comperator 504, effectively achieving Z4=‘0’.

The implementation described in relations to FIG. 7 is designed so that for a proper standardized encoded bitstream of a suffix, only one of the bits labeled Z1-Z4 is a ‘1’, and the rest are ‘0’, where the location of the ‘1’ indicates the magnitude of the binarized suffix length.

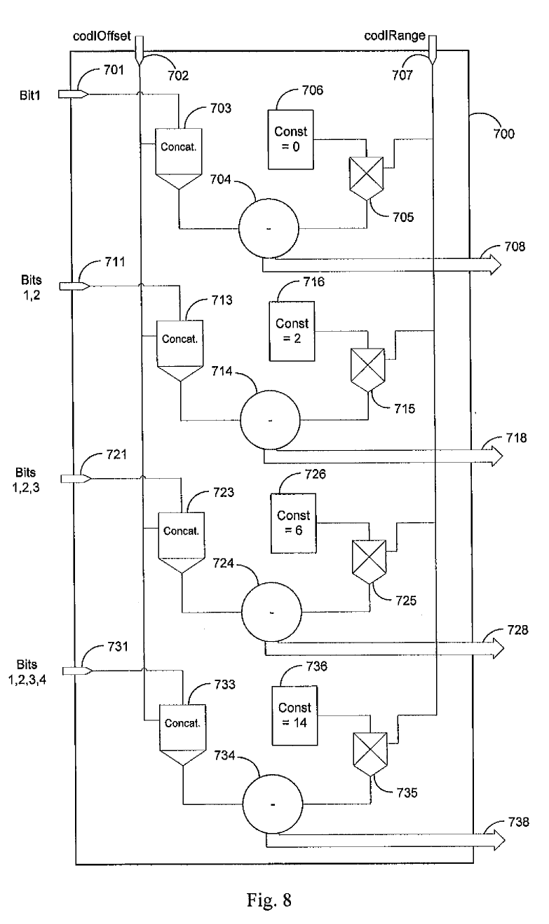

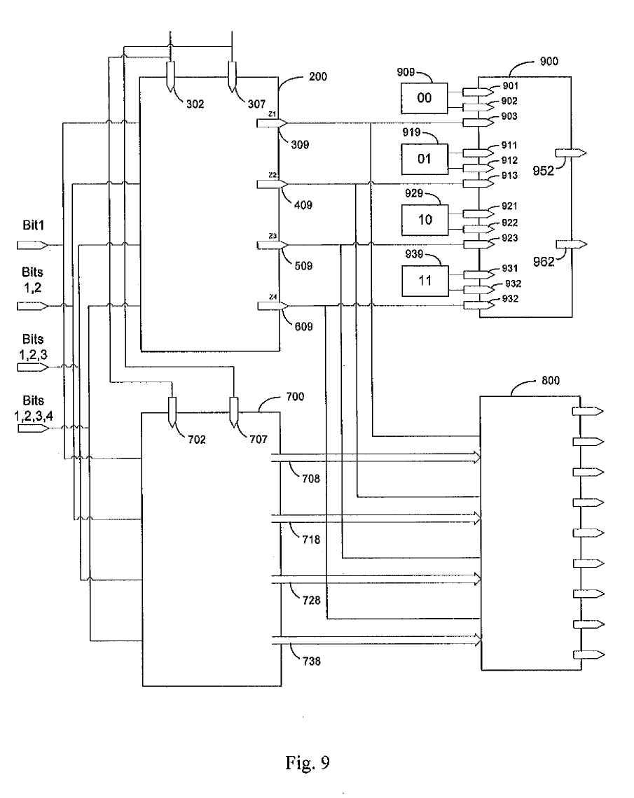

FIG. 8 is a block diagram of an implementation of a codIOffset speculation circuit, according to an embodiment of the invention. For the sake of brevity the following description deals with the parallel processing of 4 bins, although the system may be configured to process other numbers of bins. The input parameters of the circuit 700 are the codIOffset, codIRange and the first 4 bits of the suffix part of the bitstream, labeled Bit1, Bit2, Bit3, and Bit4. At first, Bit1 from input 701 is concatenated to the right end (i.e. to the LSB) of codIOffset sequence from input 702 using concatenator 703. The concatenation process is very fast in terms of processing time, and mathematically equivalent to multiplying the codIOffset by “2” and adding Bit1. At the same time CodIRange from input 707 is multiplied by a constant of “0”, stored in buffer 706, using multiplier 705. The result from multiplier 705 is then subtracted from the concatenated result from concatenator 703, by subtractor 704. The produced result of subtractor 704 is then sent to output 708. Output 708 is designed as a 9-line bus for carrying the resulting bits from subtractor 704, therefore, if the resulting bits are more than 9 bits, only the 9 LSB bits are sent to output 708. Simultaneously to the above described process, Bit1 and Bit2 from input 711 are processed similarly by the components 713-716 which function as components 703-706 respectively, excluding the constant in buffer 716 which is a “2”. The concatenation process of concatenator 713 is mathematically equivalent to multiplying the codIOffset by “2”, adding Bit1, multiplying the result by “2” and adding Bit2. The produced result of subtractor 714 is then sent to output 718, which is similar to output 708. The other two inputs: from input 721 (three bits: Bit1, Bit2, and Bit3) and from input 731 (four bits: Bit1, Bit2, Bit3, and Bit4), are also processed similarly by components 723-726 and 733-736 respectively. Components 723-726 and 728 function similarly to components 703-706 and 708 respectively, excluding the constant in buffer 726 which is a “6”. Components 733-736 and 738 function similarly to components 703-706 and 708 respectively, excluding the constant in buffer 736 which is a “14”. Thus the system processes the 4 terraced incomes separately and simultaneously, for producing a total outcome of 4 streams of 9 bits each. These 4 outcome streams of 9 bits each are 4 possible new codIOffsets. Although for the sake of time saving, all the 4 possible new codIOffsets have been produced, however, only one of these codIOffsets will eventually be selected as the codIOffset outcome of the system (described below in relations to FIG. 9). The Constants required for storage in Const 706, 716, 726, and 736 can be derived using a simple function:

Const=2ⁱ⁺¹−2

where i is a whole number which starts from 0 for the first input and increases by 1 for each new input. Since all the constants are known before implementation, they may be hardwired in the system 700 during fabrication.

For the sake of brevity an example is set forth for demonstrating the process of circuit 700 as described in relations to FIG. 8. Continuing the example disclosed above in relation to FIG. 7, codIOffset=“400” and codIRange=“500” and the first 4 bits of the suffix part of the received bitstream are: Bit1=‘1’, Bit2=‘1’, Bit3=‘0’, and Bit4=‘0’. Concatenator 703 concatenates Bit1 to the codIOffset which produces “801”. Multiplier 705 produces the codIRange multiplied by “0” which is “0”. Subtractor 704 produces the result “801” over bus 708, however, since bus 708 carries only the 9 LSB bits, the carried result over bus 708 is “289”. It should be mentioned that a result having more than 9 bits is not possible according to the H.264 standard anyway and this result of more than 9 bits will be discarded by the other circuits of the invention in due course.

Concatenator 713 concatenates Bit1 and Bit2 to the codIOffset which produces “1603”. Multiplier 715 produces the codIRange multiplied by 2 which is “1000”. Subtractor 714 produces the result “603”, which is carried over the 9 bit bus 718 as “91”. Concatenator 723 concatenates Bit1, Bit2 and Bit3 to the codIOffset which produces “3206”. Multiplier 725 produces the codIRange multiplied by 6 which is “3000”. Subtractor 724 produces the result “206” over bus 728. Concatenator 733 concatenates Bit1, Bit2, Bit3 and Bit4 to the codIOffset which produces “6412”. Multiplier 735 produces the codIRange multiplied by 14 which is “7000”. Subtractor 734 produces the result “−588”, which is carried over the 9 bit bus 738 as “436”.

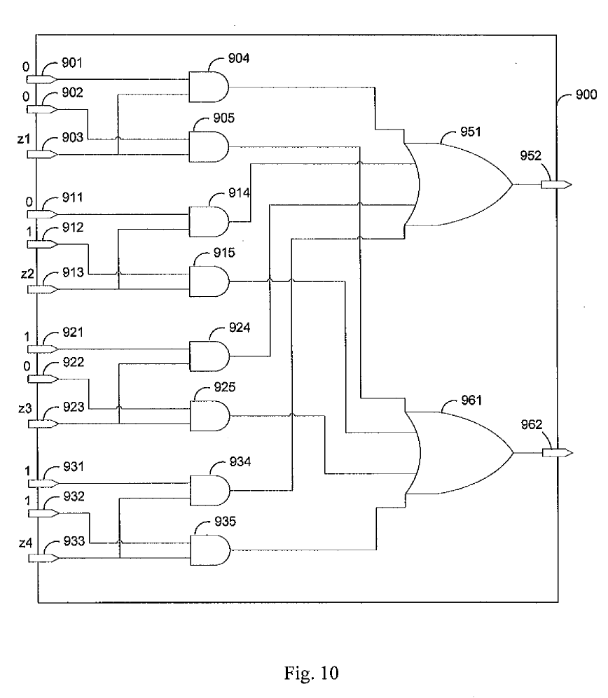

FIG. 9 is a block diagram illustrating the combination of the 4-bit processing circuit 200 of FIG. 7 with the 4-bit speculation circuit 700 of FIG. 8, according to an embodiment of the invention. For the sake of brevity the following description deals with the parallel processing of 4 bins, although the system may be configured to process other numbers of bins. As shown, the circuit 200 outputs are combined twice, once, in block 900, with known constants for producing the binstream suffix length, and once, in block 800, with the speculation circuit 700 outputs for producing the new codIOffset. The combination of inputs in block 900 will be described later in detail in relations to FIG. 10, however, the function of block 900 may be understood as a mathematical equivalent of multiplication and adding. The multiplication is between the set constants, i.e. stored in buffers 909, 919, 929, 939, and Z1-Z4, respectively, and the adding is the logical adding of all these multiplication results. As described in relations to FIG. 7 only one of the bits in Z1-Z4 is expected to be a ‘1’ therefore only one of the constants will be outputted from block 900. Similarly, the speculated codIOffsets, i.e. outputs on buses 708, 718, 728, and 738, are also combined in block 800, like in block 900, for effectively outputting only one of them as the new codIOffset.

For the sake of brevity the example described in relations to FIG. 7 and FIG. 8 is continued in relations to FIG. 9. As described Z1=‘0’, Z2=‘0’, Z3=‘1’, and Z4=‘0’. Bus 708 carries “289”, bus 718 carries “91”, bus 728 carries “206”, and bus 738 carries “436”. Therefore, when multiplying Z1 with ‘00’ from buffer 909, the result is “0”. When multiplying Z2 with ‘01’ from buffer 919, the result is “0”. When multiplying Z3 with ‘10’ from buffer 929, the result is ‘10’, meaning a decimal “2”. When multiplying Z4 with ‘11’ from buffer 939, the result is “0”. After adding all these results the combined outcome is a decimal “2” (i,e. a binary ‘10’). Similarly, when multiplying Z1 with “289” from bus 708, the result is “0”. When multiplying Z2 with “91” from bus 718, the result is “0”. When multiplying Z3 with “206” from bus 728, the result is “206”. When multiplying Z4 with “436” from bus 738, the result is “0”. After adding all these results the combined outcome is “206”, which is the new codIOffset.

FIG. 10 is a block diagram illustrating an implementation of a function for combining bits, according to an embodiment of the invention. The system 900 inputs 903, 913, 923, and 933 receive Z1-Z4 respectively. The other inputs receive constants in a binary progressive sequence, where inputs 901-902 receive ‘00’, input 911-912 receive ‘01’ respectively, inputs 921-922 receive ‘10’ respectively, and inputs 931-932 receive ‘11’. For the sake of brevity, only elements 901-905 will be described, the other corresponding elements function in similarly the same way. When Z1 is received from input 903 it is sent to AND gate 904 and AND gate 905. In AND gate 904 it is logically ANDed with the bit from input 901, e.g. the ‘0’ bit. In AND gate 905 it is logically ANDed with the bit from input 902, e.g. the ‘0’ bit. Elements 911-915, 921-925, and 931-935 function similarly as elements 901-905 respectively, where some of the input bits vary accordingly. The results from AND gates 904, 914, 924, and 934 are all entered to OR gate 951 and the result is transferred to output 952. Similarly, the results from AND gates 905, 915, 925, and 935 are all entered to OR gate 961 and the result is transferred to output 962. The results of outputs 952 and 962 are concatenated, where the result of output 952 is the MSB, for producing the value of the suffix length.

For the sake of brevity the example described in relations to FIG. 7, FIG. 8 and FIG. 9 is continued in relations to FIG. 10. As described Z1=‘0’, Z2=‘0’, Z3=‘1’, and Z4=‘0’. Therefore the outputs of AND gates 904, 905, 914, 915, 925, 934, and 935 is ‘0’, and only AND gate 924 outputs ‘1’. OR gate 951 outputs a ‘1’ and OR gate 961 outputs a ‘0’ effectively outputting together a binary sequence ‘10’ (i.e. a decimal “2”).

Block 800 described in FIG. 9 functions similarly to block 900 described in relations to FIG. 10. The outputs on connecting buses are combined with the Z1-Z4 each. Meaning that the output on bus 708 is combined with Z1 from 309, the output on bus 718 is combined with Z2 from 409, the output on 728 is combined with Z3 from 509, and the output on bus 738 is combined with Z4 from 609. In block 800 the received Z1 is sent to 9 AND gates. The 9 bits received from bus 708 are sent each to one of these 9 AND gates. Similarly, the bits from bus 718 are each logically ANDed with the received Z2, the bits from bus 728 are each logically ANDed with the received Z3, and the bits from bus 738 are each logically ANDed with the received Z4. The results of the AND gates processing the first bits of the outputs received from all the buses are entered into a first OR gate. Similarly, the results of the AND gates processing the second bits received from all the buses are entered into a second OR gate, and so on until the processing of all the ninth bits. The results of all the 9 OR gates are outputted as the new codIOffset.

In a preferred embodiment, the above described implementation of FIG. 7, FIG. 8, FIG. 9, and FIG. 10, is used for decoding 16 suffix bits from an encoded bitstream. The circuit 200 is designed to receive 16 terraced inputs, starting from the first bit as the first input continuing with the first two bits as second input and concluding with all the 16 bits as the sixteenth input. The circuit 200 constants are (in ascending order): {1, 3, 7, 15, 31, 63, 127, 255, 511, 1023, 2047, 4095, 8191, 16383, 32767, and 65553}, respectively. Similarly, the circuit 700 is designed to receive 16 terraced inputs, starting from the first bit as the first input continuing with the first two bits as second input and concluding with all the 16 bits as the sixteenth input. The circuit 700 constants are (in ascending order): {0, 2, 6, 14, 30, 62, 126, 254, 510, 1022, 2046, 4094, 8190, 16382, 32766, and 65534}, respectively. The set constants for inputting into block 900 are 0-15 in binary form, i.e. {0000, 0001, 0010 . . . 1111}.

In one of the embodiments, the described invention may be used for error finding. As described in relations to FIG. 7 and FIG. 9, the outputs of circuit 200 Z1-Z4 are designed so that for a proper standardized encoded bitstream of a suffix only one of the bits labeled Z1-Z4 is a ‘1’, and the rest are ‘0’. Therefore, an error detecting circuit may be added for detecting that if more than one of the labeled Z1-Z4 is a ‘1’ or if none of the labeled Z1-Z4 is a ‘1’ an error is declared.

In one of the embodiments, the invention may be used for processing the length of the bitstream suffix in parts. The number of bitstream suffix bits may be partitioned into clusters of suffix bits, where each cluster is processed separately. The first cluster may be processed as described in relation to FIG. 9. At the outputs of block 200 a circuit is added for checking if a ‘1’ was outputted in one of the outputs Z1-Z4. If a ‘1’ is present on one of the Z1-Z4 outputs, then the decoding is finished. However, if all Z1-Z4 outputs are ‘0’ then the system continues processing the next cluster. The next cluster may also be processed as described in relation to FIG. 9 apart from the input codIOffset which is the output from the last bus of block 700 (e.g. bus 738 in FIG. 8 and FIG. 9), of the first cluster, minus the codIRange. Thus the system may continue processing the clusters until a ‘1’ is received from the outputs of circuit 200. For example, an 8 bit encoded bitstream suffix is requested for decoding on the 4-bit system described in relation FIG. 9. At start, the first 4 bits are processed as described in relation FIG. 9. Next, the output of bus 738 is read and the codIRange is subtracted from it. The result is then fed as the codIOffset, into circuit 200 and circuit 700, for the next 4 bits, which are processed as described in relation FIG. 9 with the new codIOffset. In one of the embodiments the maximum number of bitstream suffix length bits is known and therefore, if after processing all the clusters of suffix length bits all the outputs of all the cluster processing steps of circuit 200 are ‘0’, then an error is declared. In another embodiment the maximum number of bitstream suffix length bits is unknown and therefore, the processing continues until one of the outputs of circuit 200 is a ‘1’.

In one embodiment the system of the invention may be used for syntax elements of DCT coefficients type. These syntax elements use a k=0, which require the binstream suffix to belong to the EGO binarization process, with a cMax=“14”. In another embodiment the system of the invention is used for syntax elements of Motion Vectors type. These syntax elements use a k=3, which require the binstream suffix to belong to the EG3 binarization process, with a cMax=“9”. As described, the invention may be used to process any bitstream suffix bits of any syntax element as long as the suffix bits are decoded using the bypass mode as stated in the standard, and as long as the decoded bin string of the suffix length terminates in a ‘0’.

While some embodiments of the invention have been described by way of illustration, it will be apparent that the invention can be carried into practice with many modifications, variations and adaptations, and with the use of numerous equivalents or alternative solutions that are within the scope of persons skilled in the art, without departing from the invention or exceeding the scope of claims.

1. A system for the parallel processing of a number of binstream bins comprising:
a. inputs for receiving the codIOffset, the codIRange and the bitstream suffix bits;
b. a first circuit for the parallel processing of said number of said bitstream suffix bits, said codIOffset, and said codIRange for producing an indication of the binstream suffix length magnitude;
c. a second circuit for the parallel processing of said number of said bitstream suffix bits, said codIOffset, and said codIRange for producing said number of speculative codIOffsets;
d. a third circuit for combining the products of said first circuit and the products of said second circuit for producing a new codIOffset; and
e. a fourth circuit for combining the products of said first circuit with said number of constants for producing a number indicative of the binstream suffix length.

2. A system according to claim 1, where the number of bitstream suffix bits is 16.

3. A system according to claim 1, where the binstream suffix length belongs to a syntax element of a DUCT coefficient type.

4. A system according to claim 1, where the binstream suffix length belongs to a syntax element of a Motion Vector.

5. A system according to claim 1, where the system is also used for finding errors in the bitstream suffix bits.

6. A system according to claim 1, where the bitstream suffix bits are fed in a terraced form into the inputs.

7. A system according to claim 1, where the first circuit comprises:
a. inputs for receiving the codIOffset, the codIRange and said bitstream suffix bits;
b. at least one concatenator for concatenating at least one bit of said bitstream suffix to said codIOffset;
c. at least one multiplier for multiplying said codIRange by a preset constant;
d. at least one comparator for comparing products of said concatenator and said multiplier; and
e. at least one output for outputting at least one result of said at least one comparator.

8. A system according to claim 7, where the first circuit further comprises:
a. at least one inverter for inverting at least one output of said first circuit; and
b. at least one AND gate for logically ANDing at least two outputs of said first circuit.

9. A system according to claim 8, where the system is also used for finding errors, in the bitstream suffix bits, by finding that the outputs of the AND gates have more than one logical ‘1’.

10. A system according to claim 7, where the preset constant is equal to the result of the function (2ⁱ⁺¹−1) where i is a whole number which starts from 0 for the first input and increases by 1 for each new input.

11. A system according to claim 7, where the bitstream suffix bits are fed in a terraced form into the inputs.

12. A system according to claim 1, where the second circuit comprises:
a. inputs for receiving the codIOffset, the codIRange and said bitstream suffix bits;
b. at least one concatenator for concatenating at least one bit of said bitstream suffix to said codIOffset;
c. at least one multiplier for multiplying said codIRange by a preset constant;
d. at least one subtractor for subtracting the product of said multiplier from said concatenator; and
e. at least one output for outputting at least one result of said at least one subtractor.

13. A system according to claim 12, where the bitstream suffix bits are fed in a terraced form into the inputs.

14. A system according to claim 12, where the preset constant is equal to the result of the function (2ⁱ⁺¹−2) where i is a whole number which starts from 0 for the first input and increases by 1 for each new input.

15. A system for the parallel processing of a binstream suffix length in parts comprising:
a. inputs for receiving the codIOffset, the codIRange and the bitstream suffix bits;
b. a first circuit for the parallel processing of said number of said bitstream suffix bits, said codIOffset, and said codIRange for producing an indication of the binstream suffix length magnitude;
c. a second circuit for the parallel processing of said number of said bitstream suffix bits, said codIOffset, and said codIRange for producing said number of speculative codIOffsets;
d. a third circuit for combining the products of said first circuit and the products of said second circuit for producing a new codIOffset;
e. a fourth circuit for combining the products of said first circuit with said number of constants for producing a binstream suffix length;
f. a fifth circuit for subtracting said codIRange from the last output of the second circuit for producing a codIOffset ready for input for said first circuit and said second circuit of the next part; and
g. a sixth circuit for detecting if one of the outputs of said first circuit is a logical ‘1’.

16. A system according to claim 15, where the fifth circuit comprises:
a. an input for receiving the codIRange;
b. an input for receiving the last codIOffset output from the second circuit;
c. a subtractor for subtracting said codIRange from codIOffset; and
d. an output for outputting the result from said subtractor as a codIOffset for the next part of said parallel processing of said system.

17. A system according to claim 15, where the system is also used for finding errors in the bitstream suffix bits,

18. A system according to claim 15, where the bitstream suffix bits are fed in a terraced form into the inputs.

19. A system according to claim 15, where the sixth circuit is used for error detecting.
